(19) United States
(12) Patent Application Publication
(10) Pub. No.: US 2019/0338420 A1
(43) Pub. Date: Nov. 7, 2019

(54) PRESSURE SKEW SYSTEM FOR CONTROLLING CENTER-TO-EDGE PRESSURE CHANGE

(71) Applicant: Applied Materials, Inc., Santa Clara, CA (US)

(72) Inventor: Shailendra SRIVASTAVA, Fremont, CA (US)

(21) Appl. No.: 16/374,824

(22) Filed: Apr. 4, 2019

Related U.S. Application Data
(60) Provisional application No. 62/667,050, filed on May 4, 2018.

(51) Int. Cl. C23C 16/455; C23C 16/44; C23C 16/52; C23C 16/50; H01L 21/67; H01L 21/687

(52) U.S. Cl. CPC C23C 16/455; C23C 16/4412; H01L 21/68735; C23C 16/50; H01L 21/67017; C23C 16/52

(57) ABSTRACT

Embodiments described herein relate to a pressure skew system for controlling the center-to-edge pressure change in a chamber for depositing an advanced patterning film with improved overall uniformity. The pressure skew system includes pumping zones configured to be formed in a chamber, walls disposed in the pumping region. The chamber includes a processing region, a pumping region, and a pumping path connected to a pump to exhaust process gases from the pumping region. Each pumping zone corresponds to a space of the pumping region flanked by the walls. Supply conduits are connected to a corresponding pumping zone and a corresponding mass flow control device to control a flow rate of inert gas provided to the corresponding pumping zone to control a pressure in an area of the processing region.

### CROSS-REFERENCE TO RELATED APPLICATIONS

This application claims benefit of U.S. Provisional Patent Application Ser. No. 62/667,050, filed May 4, 2018, which is herein incorporated by reference.

### BACKGROUND

### Field

Embodiments of the present disclosure generally relate to chemical vapor deposition chambers having a pressure skew system disposed therein for depositing an advanced patterning film with improved overall uniformity.

### Description of the Related Art

Chemical vapor deposition (CVD) and plasma enhanced chemical vapor deposition (PECVD) are generally employed to deposit advanced patterning film on a substrate, such as a semiconductor wafer. CVD and PECVD are generally accomplished by introducing process gases into a chamber that contains a substrate. The process gases are typically directed downwardly through a gas diffuser situated near the top of the chamber. During PECVD, the process gases in the chamber are energized (e.g., excited) into a plasma by applying radio frequency (RF) power to the chamber from one or more RF sources coupled to the chamber.

The flow of process gases distributes radially (center-to-edge) across the surface of the substrate in the chamber. A majority of the flow of process gases flows through the gas diffuser to the center of the chamber. The process gases at points along the gas diffuser have a descending flow to the substrate, contact the surface of the substrate, and then have a flow parallel to the surface of the substrate. At each point of the gas diffuser, the process gases have a vertical velocity to the substrate that transfers to a horizontal flow at a horizontal velocity radially outwardly across the substrate. At each point of the gas diffuser, the vertical velocity of the process gases may not be equal. Thus, the horizontal velocity of the process gases may also not be equal, causing non-uniform residence time of the process gases over portions of the surface of the substrate. Non-uniform residence time leads to non-uniform plasma distribution across the substrate. The non-uniform residence time of the process gases and resulting non-uniform plasma distribution causes non-uniform deposition of the advanced patterning film. In particular, the non-uniform residence time affects planar and residual uniformity of the advanced patterning film.

Accordingly, what is needed in the art is a system for controlling the residence time of the process gases to affect planar and residual uniformity of the advanced patterning film.

### SUMMARY

In one embodiment, a system is provided. The system includes a chamber lid and a chamber body. The chamber body has, a pedestal disposed therein, an inner liner coupled to a pumping ring, and an outer liner. The pedestal, the inner liner, the pumping ring, and the chamber lid form a processing region. The inner liner and the outer liner form a pumping path having an inlet and an outlet. The pumping ring, the inner liner, the outer liner, and the inlet form a pumping region. Two or more walls are disposed in the pumping region. Adjacent walls of the two or more walls disposed in the pumping region form pumping zones in the pumping region. A plurality of supply conduits is included. Each supply conduit is fluidly connected to a corresponding pumping zone of the pumping zones and a corresponding flow control device. Each flow control device is configured to control a flow rate of a gas provided to the corresponding pumping zone to control a pressure in an area of the processing region and exhaust of process gases from the processing region through the outlet.

In another embodiment, a chamber is provided. The chamber includes a chamber lid and a chamber body. The chamber body has a pedestal disposed therein, an inner liner coupled to a pumping ring, and an outer liner. The pedestal, the inner liner, the pumping ring, and the chamber lid form a processing region. The inner liner and the outer liner form a pumping path having an inlet and an outlet. The pumping ring, the inner liner, the outer liner, and the inlet, form a pumping region. The chamber includes a pressure skew system. The pressure skew system has two or more walls disposed in the pumping region and a plurality of supply conduits. Two or more walls disposed in the pumping region, adjacent walls of the two or more walls disposed in the pumping region form pumping zones in the pumping region. Each supply conduit is connected to a corresponding pumping zone of the adjacent walls and a corresponding flow control device.

In yet another embodiment, a chamber is provided. The chamber includes a chamber lid and a chamber body. The chamber body has a pedestal disposed therein, an inner liner coupled to a pumping ring, and an outer liner. The pedestal, the inner liner, the pumping ring, and the chamber lid form a processing region. The inner liner and the outer liner form a pumping path having an inlet and an outlet. The pumping ring, the inner liner, the outer liner, and the inlet, form a pumping region. The chamber includes a pressure skew system. The pressure skew system has two or more walls disposed in the pumping region and a plurality of supply conduits. Two or more walls disposed in the pumping region, adjacent walls of the two or more walls disposed in the pumping region form pumping zones in the pumping region. Each supply conduit is connected to a corresponding pumping zone of the adjacent walls and a corresponding flow control device. Each flow control device is configured to control a flow rate of a gas provided to the corresponding pumping zone to control a pressure in an area of the processing region and exhaust of process gases from the processing region through the outlet.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic cross-sectional view of a chemical vapor deposition chamber having a pressure skew system disposed therein according to an embodiment.

FIG. 1B is a schematic cross-sectional view of a chemical vapor deposition chamber having a pressure skew system disposed therein according to an embodiment.

FIG. 1C is a schematic cross-sectional view of a chemical vapor deposition chamber having a pressure skew system disposed therein according to an embodiment.

FIG. 2 is a schematic top view of the pressure skew system according to an embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein relate to a pressure skew system for controlling the center-to-edge pressure change in a chamber for depositing an advanced patterning film with improved overall uniformity. The pressure skew system includes pumping zones configured to be formed in a chamber, walls disposed in the pumping region. The chamber includes a processing region, a pumping region, and a pumping path connected to a pump to exhaust process gases from the pumping region. Each pumping zone corresponds to a space of the pumping region flanked by the walls. Supply conduits are connected to a corresponding pumping zone and a corresponding mass flow control device to control a flow rate of inert gas provided to the corresponding pumping zone to control a pressure in an area of the processing region.

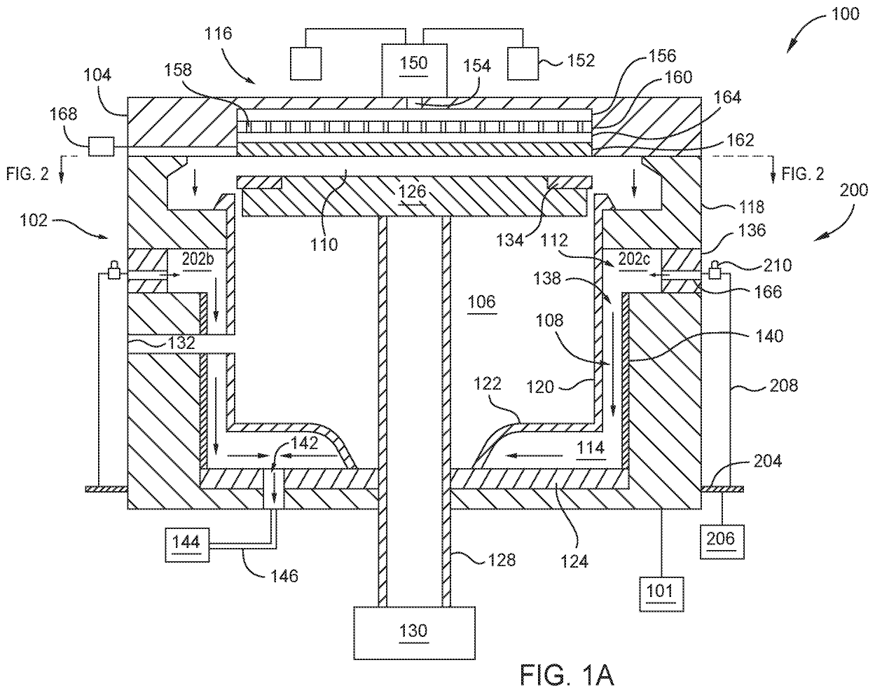

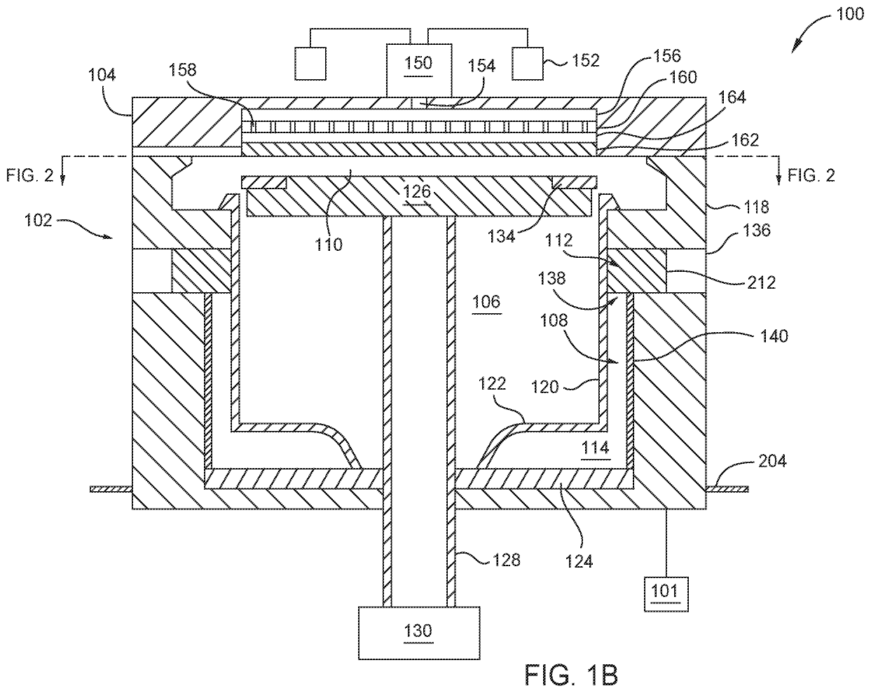

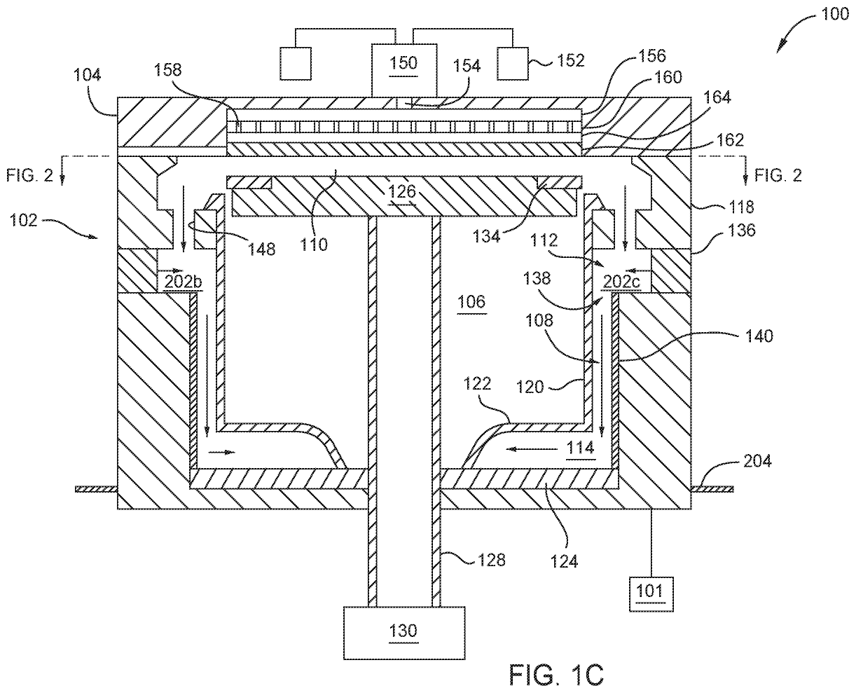

FIG. 1A is a schematic cross-sectional view of a chemical vapor deposition (CVD) chamber 100 having a pressure skew system 200 disposed therein. One example of the chamber 100 is a PRODUCER® chamber or XP PRECISION™ chamber manufactured by Applied Materials, Inc., located in Santa Clara, Calif. The chamber 100 has a chamber body 102 and a chamber lid 104. The chamber body includes processing volume 106 and a pumping volume 108. The processing volume 106 is the space defined by the chamber lid 104, a pumping ring 118, also known as an outer isolator, an inner pumping liner 120, a bottom pumping plate 122, and bottom heater 124. The inner pumping liner 120 is coupled to the pumping ring 118 and bottom pumping plate 122. The bottom pumping plate 122 is coupled to the bottom heater 124 to define the processing volume 106. The processing volume 106 has a pedestal 126 for supporting a substrate (not shown) within the chamber 100. The pedestal 126 typically includes a heating element (not shown). The pedestal 126 is movably disposed in the processing volume 106 by a stem 128 which extends through the bottom heater 124 and the chamber body 102. The stem 128 is connected to a lift system 130 that moves the pedestal 126 between an elevated processing position (as shown). The lowered position that facilitates substrate transfer to and from the processing volume 106 through a slit valve 132 formed though the chamber body 102 and the pumping volume 108 described in detail herein. The elevated processing position corresponds to a processing region 110 defined by the chamber lid 104, the pedestal 126, an edge ring 134 of the pedestal 126, the inner pumping liner 120, and pumping ring 118.

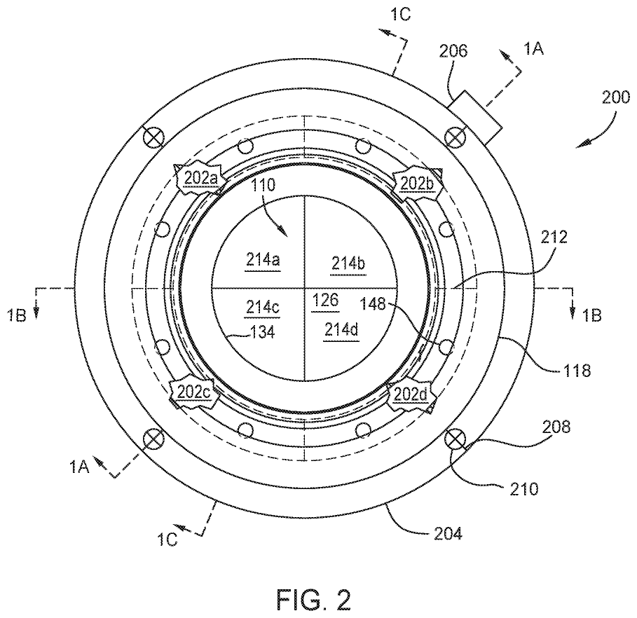

The pumping volume 108 includes include a pumping region 112 and a pumping path 114. The pumping region 112 is the space defined by the pumping ring 118, a spacer ring 136, inner pumping liner 120, and an inlet 138 of the pumping path 114. The pumping path 114 is the space defined by the inlet 138 of the pumping path 114, an outer pumping liner 140 coupled to the chamber body 102, the bottom heater 124, and an outlet disposed through the bottom heater 124 and chamber body 102. The outlet 142 of the pumping path 114 is connected to a pump 144 via the conduit 146. In one embodiment, which can be combined with other embodiments described herein, the pumping ring 118, the spacer ring 136, the inner pumping liner 120, the outer pumping liner 140, the bottom pumping plate 122, and the bottom heater 124 include ceramic containing materials. In another embodiment, which can be combined with other embodiments described herein, the pumping ring 118 includes aluminum oxide (Al₂O₃), the spacer ring includes 6061 aluminum alloy, the inner pumping liner 120 includes Al₂O₃ and/or 6061 aluminum alloy, the outer pumping liner 140 includes 6061 aluminum alloy, the bottom pumping plate 122 includes Al₂O₃, and the bottom heater 124 includes 6061 aluminum alloy. The pumping ring 118 includes holes 148 (shown in FIG. 1C and FIG. 2) that allow the pump 144 to control the pressure within the processing region 110 and to exhaust gases and byproducts from the processing region 110 through the pumping region 112 and pumping path 114. As shown in FIG. 1C, a cross-sectional view of the chamber 100 showing the holes 148 of the pumping ring 118, the holes 148 are formed through the pumping ring 118 to allow exhaust gases and byproducts from the processing region 110 to flow through the pumping region 112 and pumping path 114. The pumping ring 118 allows the flow of gases from the processing region 110 to pumping volume 108 in a manner that promotes processing within the chamber 100. In one embedment, the overall pressure within the processing region 110 is about 3 torr to about 5 torr. However, other pressures are also contemplated.

The chamber 100 also includes a gas distribution assembly 116 coupled to the chamber lid 104 to deliver a flow of one or more gases into the processing region 110. The gas distribution assembly 116 includes a gas manifold 150 coupled to a gas inlet passage 154 formed in the chamber lid 104 which receives the flow of gases from one or more gas sources 152. The flow of gases distributes across a gas box 156, flows through a plurality of holes 158 of a backing plate 160, further distributes across a plenum 168 defined by the backing plate 160 and a faceplate 162, and flows into the processing region 110 through a plurality of holes (not shown) of the faceplate 162. An RF (radio frequency) source 164 is coupled to the gas distribution assembly 116. The RF source 164 powers the gas distribution assembly 116 to facilitate generation of plasma from gases in the processing region 110. The pedestal 126 is grounded or the pedestal 126 may serve as a cathode when connected to a power supply to generate a capacitive electric field between the faceplate 162 and the pedestal 126 to accelerate plasma species toward the substrate to deposit the advanced patterning film. A controller 101 is coupled to the chamber 100 and a pressure skew system 200 of the chamber 100. The controller 101 is configured to control aspects of the chamber 100 and the pressure skew system 200 during processing.

The flow of gases distributes radially (center-to-edge) across the surface of the substrate in the processing region 110. In one embodiment, which can be combined with other embodiments described herein, a majority of the flow of gases flows through faceplate 162 to the center of the processing region 110. The gases at points along the faceplate 162 have a descending flow to the substrate, contact the surface of the substrate, and have a flow parallel to the surface of the substrate. At each point of faceplate 162, the gases have a vertical velocity to the substrate that transfers to a horizontal flow at a horizontal velocity radially outwardly across the substrate. The pump 144 exhausts the gases through the pumping ring 118, the pumping region 112, and the pumping path 114 resulting in a center-to-edge change in pressure across the substrate. At each point of the faceplate 162, the vertical velocity of the gases may not be equal. Thus, the horizontal velocity of the gases is not equal, causing non-uniform residence time of the gases over portions of the surface of the substrate. Non-uniform residence time leads to non-uniform plasma distribution across the substrate. The non-uniform residence time of the gases and resulting non-uniform plasma distribution causes non-uniform deposition of the advanced patterning film. In particular, the non-uniform residence time affects planar and residual uniformity of the advanced patterning film. Therefore, the chamber 100 includes a pressure skew system 200 to control the center-to-edge pressure change across the substrate to control the planar and residual uniformity.

FIG. 2 is a schematic top view of the pressure skew system 200 for controlling the center-to-edge pressure change in a process chamber, such as the chamber 100. The pressure skew system 200 includes at least two pumping zones. In one embodiment, which can be combined with other embodiments described herein, the pressure skew system 200 (as shown) includes four pumping zones 202a-202d. The pressure skew system 200 includes as many pumping zones as necessary to result in planar and residual uniformity of the advanced patterning film. Each pumping zone of the pumping zones 202a-202d is connected to a manifold 204 connected to an inert gas supply 206. Each pumping zone of the pumping zones 202a-202d is connected to a manifold 204 by a plurality of supply conduits 208. Each supply conduit 208 has a flow control device 210, such as a mass flow control (MFC) device, that precisely controls the flow rate of inert gas, such as nitrogen gas (N₂), hydrogen gas (H₂), argon (Ar), and helium (He), that is provided to one of the pumping zones of pumping zones 202a-202d from the manifold 204. As shown in FIG. 1A, each supply conduit 208 is connected to a channel 166 disposed through the spacer ring 136 that leads to the pumping region 112. Each pumping zone of the pumping zones 202a-202d corresponds to a space of the pumping region 112 flanked by walls 212 (shown in FIG. 1B) disposed in the pumping region 112.

FIG. 1B is another schematic cross-sectional view of the chamber 100 having a pressure skew system 200 disposed therein showing the walls 212 disposed in the pumping region 112. The walls 212 disposed in the pumping region 112 define each pumping zone of pumping zones 202a-202d in the pumping region 112. The walls 212 defining each pumping zone of pumping zones 202a-202d allow the pressure in each pumping zone to be independently controlled as gases cannot flow through the holes 148 of pumping ring 118 into the pumping region 112 and through the pumping path 114 blocked by the walls 212. Each pumping zone of pumping zones 202a-202d may have a flow rate of inert gas provided to the pumping region 212 to control the pressure change in an area of the processing region 110 to affect the horizontal velocity of the gases across the substrate, to further control the planar and residual uniformity of the deposited advanced patterning film, and thus control the overall uniformity of the deposited advanced patterning film.

Referring back to FIG. 2, each pumping zone of pumping zones 202a-202d controls the areas 214a-214d of the processing region 110. Each area of the areas 214a-214d corresponds to a region of the surface of the substrate. For example, to decrease the horizontal velocity of the gases across the area 214a of the processing region 110 and increase the residence time of the gases over a region of the surface of the substrate, the flow control device 210 controls the flow rate of inert gas provided to the pumping zone 202a from the manifold 204. The flow rate of inert gas provided to the pumping zone 202a sets the pressure in the pumping region 112 which controls the center-to-edge pressure change in the area 214a of the processing region 110. In one embodiment, which can be combined with other embodiments described herein, the center-to-edge pressure change in the area 214a-214d of the processing region 110 is about 1 torr to about 2 torr greater or less than the overall pressure within the processing region 110. In one embodiment, which can be combined with other embodiments described herein, increasing the flow rate of inert gas results in a decreased horizontal velocity and increased residence time over the region of the surface of the substrate corresponding to the areas 214a-214d. In another embodiment, which can be combined with other embodiments described herein, decreasing the flow rate of inert gas results in an increased horizontal velocity and decreased residence time over the region of the surface of the substrate corresponding to the areas 214a-214d. The flow rates provided to each pumping zone of the pumping zones 202a-202d are optimized to control the center-to-edge pressure change in each area 214a-214d of the processing region 110 to improve the overall uniformity of the deposited advanced patterning film.

In summation, a pressure skew system for controlling the center-to-edge pressure change in a CVD chamber for depositing an advanced patterning film (e.g., a carbon-containing or boron-doped-carbon hardmask) with improved overall uniformity is described herein. The utilization of the pressure skew system having at least two pumping zones where each pumping zone is connected to a manifold to an inert gas supply having a MFC device that precisely controls the flow rate of inert gas provided to each pumping zone. The flow rate of inert gas provided to each pumping zone controls the pressure change in an area of the processing region to affect the horizontal velocity of the gases across the substrate, which in turn controls the planar and residual uniformity of the deposited advanced patterning film, and thus controls the overall uniformity of the deposited advanced patterning film.

While the foregoing is directed to examples of the present disclosure, other and further examples of the disclosure may be devised without departing from the basic scope thereof, and the scope thereof is determined by the claims that follow.

What is claimed is:

1. A system, comprising:
a chamber lid;
a chamber body, the chamber body having:
a pedestal disposed therein;
an inner liner coupled to a pumping ring, wherein the pedestal, the inner liner, the pumping ring, and the chamber lid forming a processing region; and
an outer liner, wherein:
the inner liner and the outer liner form a pumping path having an inlet and an outlet; and
the pumping ring, the inner liner, the outer liner, and the inlet form a pumping region;
two or more walls disposed in the pumping region, adjacent walls of the two or more walls disposed in the pumping region forming pumping zones in the pumping region; and
a plurality of supply conduits, wherein each supply conduit is fluidly connected to a corresponding pumping zone of the pumping zones and a corresponding flow control device, wherein each flow control device is configured to control a flow rate of a gas provided to the corresponding pumping zone to control a pressure in an area of the processing region and exhaust of process gases from the processing region through the outlet.

2. The system of claim 1, wherein the processing region of the chamber body is further defined by an edge ring of the pedestal.

3. The system of claim 2, wherein the pumping region of the chamber body is further defined by a spacer ring.

4. The system of claim 3, wherein the pumping ring, the spacer ring, the inner liner, and the outer liner includes ceramic containing materials.

5. The system of claim 3, wherein the pumping ring includes aluminum oxide (Al₂O₃), the spacer ring includes 6061 aluminum alloy, the inner liner includes at least one of Al₂O₃ and 6061 aluminum alloy, and the outer liner includes 6061 aluminum alloy.

6. The system of claim 1, wherein holes are formed through the pumping ring to allow the process gases from the processing region to flow through the pumping region and the pumping path.

7. The system of claim 1, wherein each pumping zone of pumping zones controls one area of a plurality of areas of the processing region, each area corresponds to a region of a surface of the pedestal.

8. The system of claim 1, wherein each supply conduit is connected to a channel disposed through a spacer ring of the chamber body, wherein each channel leads to the pumping region.

9. The system of claim 1, wherein the pressure in the area of the processing region affects a horizontal velocity of the process gases in the processing region.

10. A chamber, comprising:
a chamber lid;
a chamber body, the chamber body having:
a pedestal disposed therein;
an inner liner coupled to a pumping ring, wherein the pedestal, the inner liner, the pumping ring, and the chamber lid forming a processing region; and
an outer liner, wherein:
the inner liner and the outer liner form a pumping path having an inlet and an outlet; and
the pumping ring, the inner liner, the outer liner, and the inlet, form a pumping region; and
a pressure skew system, the pressure skew system having:
two or more walls disposed in the pumping region, adjacent walls of the two or more walls disposed in the pumping region forming pumping zones in the pumping region; and
a plurality of supply conduits, wherein each supply conduit is connected to a corresponding pumping zone of the adjacent walls and a corresponding flow control device.

11. The chamber of claim 10, wherein each flow control device is configured to control a flow rate of inert gas provided to the corresponding pumping zone to control a pressure in an area of the processing region and exhaust of process gases from the processing region though the outlet.

12. The chamber of claim 11, wherein holes are formed through the pumping ring to allow the process gases from the processing region to flow through the pumping region and the pumping path.

13. The chamber of claim 10, wherein the processing region of the chamber is further defined by an edge ring of the pedestal and the pumping region of the chamber is further defined by a spacer ring.

14. The chamber of claim 10, wherein each pumping zone of pumping zones controls one area of a plurality of areas of the processing region, each area corresponds to a region of a surface of the pedestal.

15. The chamber of claim 10, wherein the plurality of supply conduits are connectable to a manifold connectable to an inert gas supply.

16. The chamber of claim 10, wherein each flow control device is a mass flow control (MFC) device.

17. A chamber, comprising:
a chamber lid;
a chamber body, the chamber body having:
a pedestal disposed therein;
an inner liner coupled to a pumping ring, wherein the pedestal, the inner liner, the pumping ring, and the chamber lid forming a processing region; and
an outer liner, wherein:
the inner liner and the outer liner form a pumping path having an inlet and an outlet; and
the pumping ring, the inner liner, the outer liner, and the inlet, form a pumping region; and
a pressure skew system, the pressure skew system having:
two or more walls disposed in the pumping region, adjacent walls of the two or more walls disposed in the pumping region forming pumping zones in the pumping region; and
a plurality of supply conduits, wherein each supply conduit is fluidly connected to a corresponding pumping zone of the pumping zones and a corresponding flow control device, wherein each flow control device is configured to control a flow rate of a gas provided to the corresponding pumping zone to control a pressure in an area of the processing region and exhaust of process gases from the processing region through the outlet.

18. The chamber of claim 17, wherein the pressure in the area of the processing region affects a horizontal velocity of the process gases in the processing region.

19. The chamber of claim 17, wherein holes are formed through the pumping ring to allow the process gases from the processing region to flow through the pumping region and the pumping path.

20. The chamber of claim 17, wherein each pumping zone of pumping zones controls one area of a plurality of areas of the processing region, each area corresponds to a region of a surface of the pedestal.
